(19) United States
(12) Patent Application Publication
(10) Pub. No.: US 2022/0392932 A1
(43) Pub. Date: Dec. 8, 2022

(54) INTER-PIXEL SUBSTRATE ISOLATION

(71) Applicant: Quantum-Si Incorporated, Guilford, CT (US)

(72) Inventor: Eric A.G. Webster, Mountain View, CA (US)

(21) Appl. No.: 17/831,394

(22) Filed: Jun. 2, 2022

Related U.S. Application Data
(60) Provisional application No. 63/196,614, filed on Jun. 3, 2021.

(51) Int. Cl. H01L 27/146

(52) U.S. Cl. CPC H01L 27/14603; H01L 27/14643; H01L 27/14689

(57) ABSTRACT

Aspects of the technology described herein relate to improved semiconductor-based image sensor designs. In some embodiments, an integrated circuit may comprise a plurality of photodetection regions and one or more intermediate regions between the photodetection regions. In some embodiments, the intermediate regions may comprise bulk semiconductor material that facilitates a transfer of noise charge carriers from the intermediate regions to drain regions associated with each photodetection region. In some embodiments, a drain device may be configured with a gate controlling the flow of charge carriers from the intermediate regions and photodetection regions to drain regions. In some embodiments, an integrated circuit may comprise an array of pixels and a control circuit configured to control a transfer of charge carriers in the array of pixels.

### RELATED APPLICATIONS

This application claims the benefit under 35 U.S.C. § 119(e) of U.S. Provisional Application Ser. No. 63/196,614, filed Jun. 3, 2021, under Attorney Docket No.: R0708.70134US00, and entitled, “INTER-PIXEL SUBSTRATE ISOLATION,” which is herein incorporated by reference in its entirety.

### FIELD OF THE DISCLOSURE

The present disclosure relates to integrated devices and related instruments that can perform massively-parallel analyses of samples by providing short optical pulses to tens of thousands of sample wells or more simultaneously and receiving fluorescent signals from the sample wells for sample analyses. The instruments may be useful for point-of-care genetic sequencing and for personalized medicine.

### BACKGROUND

Photodetectors are used to detect light in a variety of applications. Integrated photodetectors have been developed that produce an electrical signal indicative of the intensity of incident light. Integrated photodetectors for imaging applications include an array of pixels to detect the intensity of light received from across a scene. Examples of integrated photodetectors include charge coupled devices (CCDs) and Complementary Metal Oxide Semiconductor (CMOS) image sensors.

Instruments that are capable of massively-parallel analyses of biological or chemical samples are typically limited to laboratory settings because of several factors that can include their large size, lack of portability, requirement of a skilled technician to operate the instrument, power need, need for a controlled operating environment, and cost. When a sample is to be analyzed using such equipment, a common paradigm is to extract a sample at a point of care or in the field, send the sample to the lab and wait for results of the analysis. The wait time for results can range from hours to days.

### SUMMARY OF THE DISCLOSURE

Some aspects of the present disclosure relate to an integrated circuit, comprising a surface, a first photodetection region, a second photodetection region, and an intermediate region situated between the first and second photodetection regions, wherein the first and second photodetection regions and the intermediate region are positioned along the surface, and wherein the intermediate region comprises bulk semiconductor material.

Some aspects of the present disclosure relate to an integrated circuit, comprising a first photodetection region, a second photodetection region, an intermediate region between the first and second photodetection regions, a first drain region, and a first drain device electrically coupled to the first photodetection region, wherein the first drain device and the intermediate region are configured to cause charge carriers to flow from the intermediate region to the first drain region.

Some aspects of the present disclosure relate to a method of manufacturing an integrated circuit, the method comprising forming a surface, forming a first photodetection region, forming a second photodetection region, and forming an intermediate region situated between the first and second photodetection regions, wherein the first and second photodetection regions and the intermediate region are positioned along the surface, wherein the intermediate region comprises bulk semiconductor material, and wherein in the integrated circuit, as manufactured, the intermediate region abuts the surface.

The foregoing summary is not intended to be limiting. In addition, various embodiments may include any aspects of the disclosure either alone or in combination.

### BRIEF DESCRIPTION OF DRAWINGS

FIG. 1-1 is a partial schematic of an integrated device, according to some embodiments.

FIG. 1-2A is a partial schematic of a row of pixels of the integrated device of FIG. 1-1, according to some embodiments.

FIG. 1-2B is a side view of a cross-section of the row of pixels partially shown in FIG. 1-2A, according to some embodiments.

FIG. 1-3A is a partial schematic of the row of pixels partially shown in FIG. 1-2A further illustrating a plurality of contacts, according to some embodiments.

FIG. 1-3B is a side view of a cross-section of the row of pixels partially shown in FIG. 1-3A, according to some embodiments.

FIG. 1-4 is a magnified schematic of the photodetection region of a pixel in the row of pixels partially shown in FIG. 1-2A, according to some embodiments.

FIG. 1-5 is a partial schematic of an alternative row of pixels that may be included in the integrated device of FIG. 1-1, according to some embodiments.

FIG. 1-6A is a partial schematic of a further alternative row of pixels that may be included in the integrated device of FIG. 1-1, according to some embodiments.

FIG. 1-6B is a side view of a cross-section of the row of pixels partially shown in FIG. 1-6A, according to some embodiments.

FIG. 1-6C is a side view of another cross-section of the row of pixels partially shown in FIG. 1-6A, according to some embodiments.

FIG. 1-7 is a partial schematic of an alternative integrated device, according to some embodiments.

FIG. 2-1A is a block diagram of an integrated device and an instrument, according to some embodiments.

FIG. 2-1B is a block diagram depiction of an analytical instrument that includes a compact mode-locked laser module, according to some embodiments.

FIG. 2-1C depicts a compact mode-locked laser module incorporated into an analytical instrument, according to some embodiments.

FIG. 2-2 depicts a train of optical pulses, according to some embodiments.

The features and advantages of the present invention will become more apparent from the detailed description set forth below when taken in conjunction with the drawings. When describing embodiments in reference to the drawings, directional references (“above,” “below,” “top,” “bottom,” “left,” “right,” “horizontal,” “vertical,” etc.) may be used. Such references are intended merely as an aid to the reader viewing the drawings in a normal orientation. These directional references are not intended to describe a preferred or only orientation of features of an embodied device. A device may be embodied using other orientations.

### DETAILED DESCRIPTION

### I. Introduction

Aspects of the present disclosure relate to integrated devices, instruments, and related systems capable of analyzing samples in parallel, including identification of single molecules and nucleic acid sequencing. Such an instrument may be compact, easy to carry, and easy to operate, allowing a physician or other provider to readily use the instrument and transport the instrument to a desired location where care may be needed. Analysis of a sample may include labeling the sample with one or more fluorescent markers, which may be used to detect the sample and/or identify single molecules of the sample (e.g., individual nucleotide identification as part of nucleic acid sequencing). A fluorescent marker may become excited in response to illuminating the fluorescent marker with excitation light (e.g., light having a characteristic wavelength that may excite the fluorescent marker to an excited state) and, if the fluorescent marker becomes excited, emit emission light (e.g., light having a characteristic wavelength emitted by the fluorescent marker by returning to a ground state from an excited state). Detection of the emission light may allow for identification of the fluorescent marker, and thus, the sample or a molecule of the sample labeled by the fluorescent marker. According to some embodiments, the instrument may be capable of massively-parallel sample analyses and may be configured to handle tens of thousands of samples or more simultaneously.

The inventors have recognized and appreciated that an integrated device having sample wells configured to receive the sample and integrated optics formed on the integrated device and an instrument configured to interface with the integrated device may be used to achieve analysis of this number of samples. The instrument may include one or more excitation light sources, and the integrated device may interface with the instrument such that the excitation light is delivered to the sample wells using integrated optical components (e.g., waveguides, optical couplers, optical splitters) formed on the integrated device. The optical components may improve the uniformity of illumination across the sample wells of the integrated device and may reduce a large number of external optical components that might otherwise be needed. Furthermore, the inventors have recognized and appreciated that integrating photodetection regions (e.g., photodiodes) on the integrated device may improve detection efficiency of fluorescent emissions from the sample wells and reduce the number of light-collection components that might otherwise be needed.

In some embodiments, the integrated device may be configured to receive fluorescent emission photons from the sample wells and generate and transmit charge carriers to one or more charge storage regions in response to receiving the fluorescent emission photons. For example, a photodetection region may be positioned on the integrated device and configured to receive the fluorescent emission charge carriers along an optical axis, and the photodetection region also may be coupled to one or more charge storage regions (e.g., storage diodes) along an electrical axis, such that the charge storage region(s) may collect charge carriers generated in the photodetection region in response to the fluorescent emission charge carriers. In some embodiments, the integrated device can be configured to receive one or more control signals at one or more transfer gates that control a transfer of charge carriers from the photodetection region to the charge storage region(s) for later readout.

Challenges arise in collecting fluorescent emission charge carriers in the charge storage regions due to the relatively small quantity of fluorescent emission charge carriers compared to excitation charge carriers that may reach the integrated device. For instance, excitation photons from the excitation source may reach the photodetectors and generate noise charge carriers that would be indistinguishable from fluorescent emission charge carriers if they were to reach the charge storage regions. Thus, excitation photons can add noise to detected fluorescent emissions in the photodetectors.

In some embodiments, during a discarding period (e.g., preceding a collection period), a drain region of the integrated device may receive noise charge carriers for discarding (e.g., excitation charge carriers generated responsive to incident excitation photons) from, e.g., the photodetection region. For example, noise charge carriers may be conducted to a direct current (DC) voltage source. In some embodiments, the drain region of the integrated device can be coupled to the photodetection region by a drain charge transfer channel. In some embodiments, the integrated device can be configured to receive a drain control signal at a drain gate that controls a transfer of charge carriers from the photodetection region to the drain region. In some embodiments, the integrated device can be configured to perform a collection sequence including a discarding period; a collection period, during which charge storage region(s) may receive fluorescent emission charge carriers from at least the photodetection region; and a readout period, during which the charge storage region(s) may provide the stored charge carriers to a readout circuit for processing.

The inventors have recognized the importance of providing sufficient electrical isolation between neighboring photodetection regions, e.g., of adjacent pixels, to prevent neighboring photodetection regions from adversely impacting one another. For example, a photodetection region could adversely impact a neighboring photodetection region by punch-through, in which the depletion regions of the photodetection regions overlap and form an undesirable current path between photodetection regions. The inventors have discovered, however, that techniques in common use for achieving electrical isolation between photodetection regions such as shallow trench isolation (STI) and/or moderately to heavily doped regions of opposite doping type to the photodetection regions (e.g., low threshold voltage p-well) can prevent effective removal of noise charge carriers from the intermediate region between adjacent photodetection regions during the discarding period. The inventors have recognized that, during a discarding period, an electric field incident upon a photodetection region or regions may fail to extend into regions underneath or nearby an STI and/or moderately to heavily doped isolation region, allowing significant numbers of noise charge carriers to linger between the photodetection regions. Failure to remove noise charge carriers can degrade the signal obtained during collection and readout periods. For instance, noise charge carriers can travel beyond the photodetection region and/or reach undesired locations in a pixel, such as a charge storage region. If unmitigated, the noise charge carriers can impact the accuracy of charge readouts from the pixel.

To solve the above problems, the inventors have developed techniques to prevent noise charge carriers from reaching the charge storage regions. For instance, before fluorescent emission charge carriers reach a pixel, it is desirable to discard, from the photodetection regions and from the intermediate regions between photodetection regions, as many excitation charge carriers that are generated in response to excitation photons as possible to prevent the excitation charge carriers from being transported to the charge storage region as noise. Accordingly, the inventors developed techniques for expanding the depletion regions of photodetection regions laterally, thus allowing photodetection regions to influence charge carriers beyond the photodetection regions. For example, an electric field applied to a photodetection region can exert a force on charge carriers in the region between adjacent photodetection regions and/or between adjacent pixels, to cause the charge carriers to move to the drain regions within the pixels. These techniques also ensure sufficient isolation between adjacent photodetection regions to prevent punch-through at useful voltages for detection of the fluorescence signal of interest. In some embodiments, bulk silicon (e.g., epitaxial silicon material present at the start of CMOS processing) that is, at most, only lightly doped, as described below, is used in the intermediate regions between adjacent photodetection regions. In some embodiments, these intermediate regions are regions between pixels in an array of pixels. In some embodiments, each pixel has a photodetection region. In this manner, the inventors have avoided isolation techniques that inhibit electric fields from acting on charge carriers in the regions between photodetection regions and thus inhibit discarding of noise charge carriers.

It should be appreciated that integrated devices described herein may incorporate any or all techniques described herein alone or in combination. It should also be appreciated that STI barriers may be used in at least some portions of pixels described herein without departing from the scope of the technology developed herein, as embodiments are not so limited.

### II. Example Integrated Device Overview

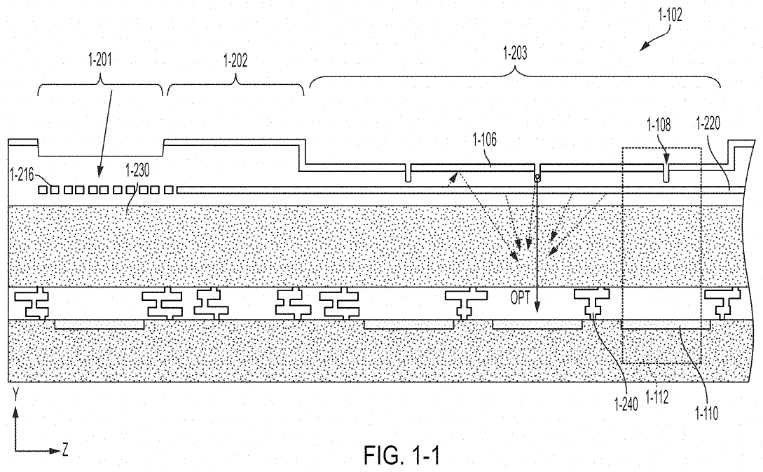

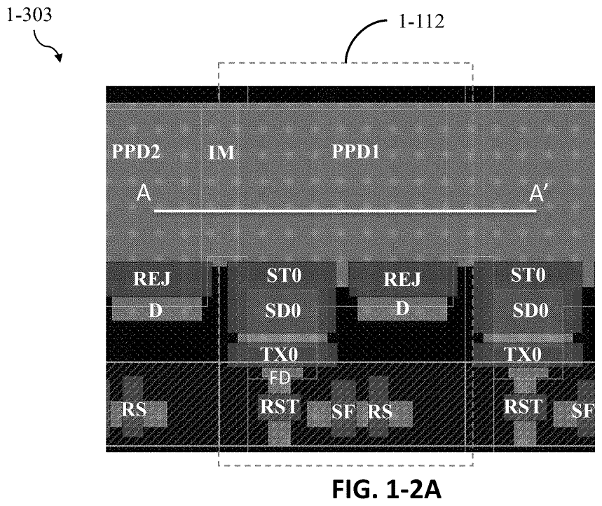

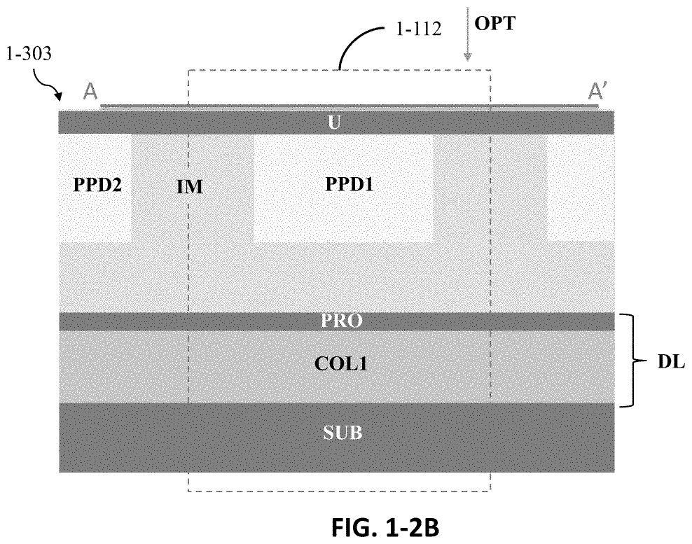

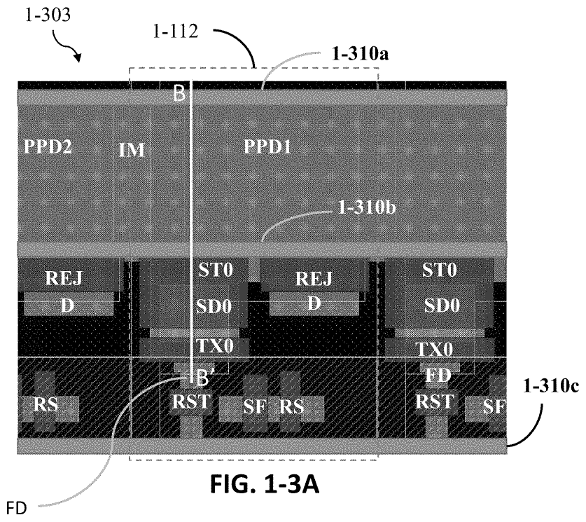

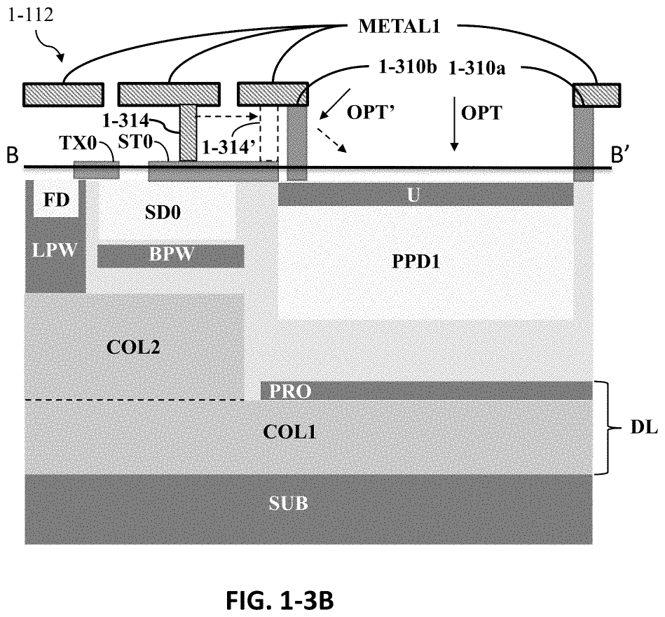

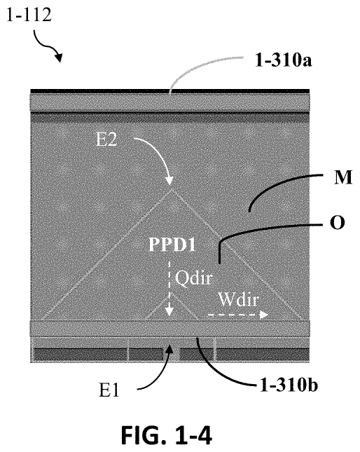

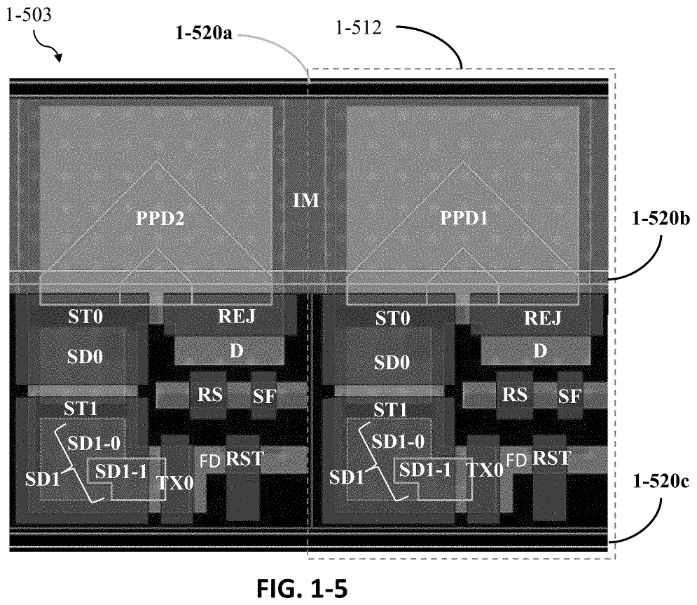

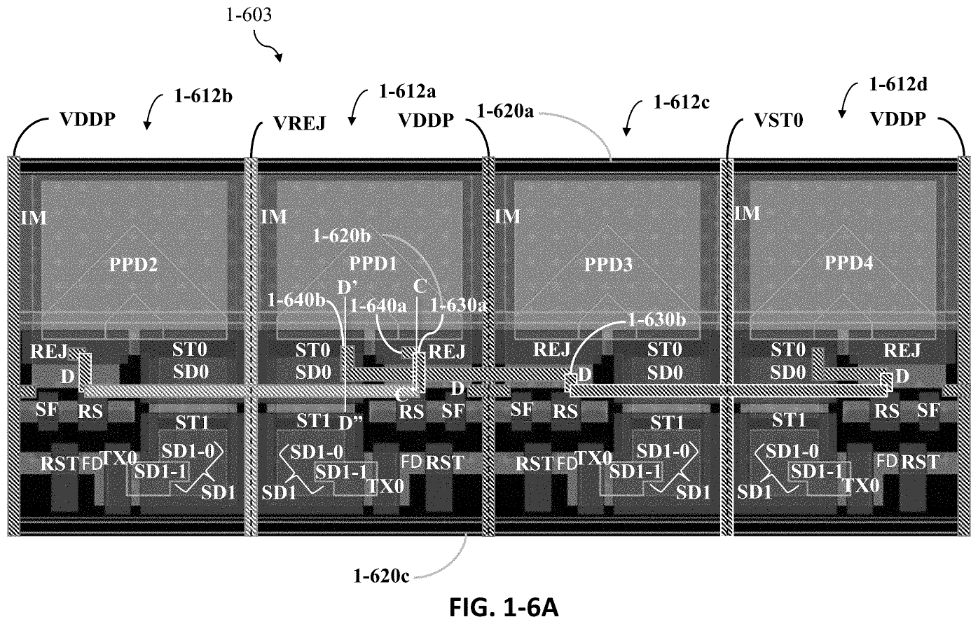

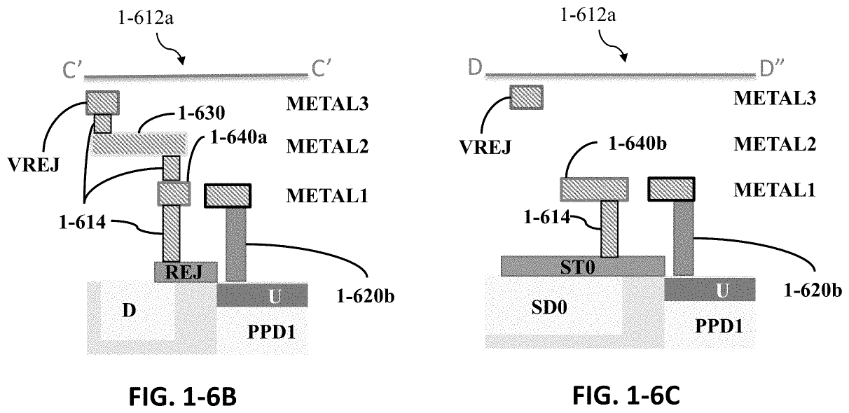

A cross-sectional schematic of integrated device 1-102 illustrating a row of pixels 1-112 is shown in FIG. 1-1, according to some embodiments. Integrated device 1-102 may include coupling region 1-201, routing region 1-202, and pixel region 1-203. Coupling region 1-201 may be configured to receive incident excitation light from an excitation light source. Routing region 1-202 may be configured to deliver the excitation light from coupling region 1-201 to pixel region 1-203. Pixel region 1-203 may include a plurality of sample wells 1-108 positioned on a surface at a location separate from coupling region 1-201. For example, coupling region 1-201 may include one or more grating couplers 1-216 and routing region 1-202 may include one or more waveguides 1-220 configured to propagate light from grating coupler(s) 1-216 under sample well(s) 1-108. For instance, evanescent coupling of excitation light from waveguide(s) 1-220 may excite samples in sample well(s) 1-108 to emit fluorescent light.

As shown in FIG. 1-1, one or more at least partially opaque (e.g., metal) layers 1-106 can be disposed over the surface to reflect incident excitation light coupled from waveguide(s) 1-220. Sample wells 1-108 may be free of layer(s) 1-106 to allow samples to be placed in sample well(s) 1-108. In some embodiments, the directionality of the emission light from a sample well 1-108 may depend on the positioning of the sample in the sample well 1-108 relative to metal layer(s) 1-106 because metal layer(s) 1-106 may act to reflect emission light. In this manner, a distance between metal layer(s) 1-106 and a fluorescent marker on a sample positioned in a sample well 1-108 may impact the efficiency of photodetector(s) 1-110, that are in the same pixel as the sample well, to detect the light emitted by the fluorescent marker. The distance between metal layer(s) 1-106 and the bottom surface of a sample well 1-108, which is proximate to where a sample may be positioned during operation, may be in the range of 100 nm to 500 nm, or any value or range of values in that range. In some embodiments the distance between metal layer(s) 1-106 and the bottom surface of a sample well 1-108 is approximately 300 nm.

As shown in FIG. 1-1, pixel region 1-203 can include one or more rows of pixels 1-112. One pixel 1-112, illustrated by the dotted rectangle, is a region of integrated device 1-102 that includes a sample well 1-108 and one or more photodetectors 1-110 (e.g., including a photodetection region) associated with the sample well 1-108. In some embodiments, each photodetector 1-110 can include a photodetection region and one or more charge storage regions configured to receive charge carriers generated in the photodetection region in response to incident light from the sample well 1-108. When excitation light coupled from waveguide(s) 1-220 illuminates a sample located within the sample well 1-108, the sample may reach an excited state and emit emission light. The emission light may be detected by one or more photodetectors 1-110 associated with the sample well 1-108. FIG. 1-1 schematically illustrates an optical axis OPT of emission light from a sample well 1-108 to photodetector(s) 1-110 of pixel 1-112. The photodetector(s) 1-110 of pixel 1-112 may be configured and positioned to detect emission light from sample well 1-108. For an individual pixel 1-112, a sample well 1-108 and its respective photodetector(s) 1-110 may be aligned along a common optical axis. In this manner, the photodetector(s) 1-110 may overlap with the sample well 1-108 within a pixel 1-112.

Also shown in FIG. 1-1, integrated device 1-102 can include one or more photonic structures 1-230 and/or metal layers 1-240 positioned between sample wells 1-108 and photodetectors 1-110. For example, photonic structures 1-230 may be configured to increase the amount of emission light that reaches photodetectors 1-110 from sample wells 1-108. Alternatively or additionally, photonic structures 1-230 may be configured to reduce or prevent excitation light from reaching photodetectors 1-110, which may otherwise contribute to signal noise in detecting the emission light. As shown in FIG. 1-1, photonic structures 1-230 may be positioned between waveguide(s) 1-220 and photodetectors 1-110. According to various embodiments, photonic structures 1-230 may include one or more optical rejection photonic structures including a spectral filter, a polarization filter, and a spatial filter. In some embodiments, photonic structures 1-230 may be positioned to align with individual sample wells 1-108 and their respective photodetector(s) 1-110 along a common axis.

In some embodiments, metal layers 1-240 may be configured to route control signals to and/or from portions of integrated device 1-102. For example, the control signals may be received from a control circuit within and/or coupled to one or more conductive pads (not shown) of integrated device 1-102 and routed to pixels 1-112 via metal layers 1-240. In some embodiments, metal layers 1-240 may also act as a spatial and/or polarization filter. In such embodiments, one or more metal layers 1-240 may be positioned to block some or all excitation light from reaching photodetector(s) 1-110.

In some embodiments, the distance between the sample and the photodetector(s) may also impact efficiency in detecting emission light. By decreasing the distance light has to travel between the sample and the photodetector(s) 1-110, detection efficiency of emission light may be improved. In addition, smaller distances between the sample and the photodetector(s) 1-110 may allow for pixels that occupy a smaller area footprint of the integrated device, which can allow for a higher number of pixels to be included in the integrated device. The distance d between the bottom surface of a sample well 1-108 and the photodetector(s) 1-110 may be in the range of 5 μm to 15 μm, or any value or range of values in that range, in some embodiments, but the invention is not so limited. It should be appreciated that, in some embodiments, emission light may be provided through other means than an excitation light source and a sample well. Accordingly, some embodiments may not include sample well 1-108.

A sample to be analyzed may be introduced into sample well 1-108 of pixel 1-112. The sample may be a biological sample or any other suitable sample, such as a chemical sample. The sample may include multiple molecules and the sample well may be configured to isolate a single molecule. In some instances, the dimensions of the sample well 1-108 may act to confine a single molecule within the sample well 1-108, allowing measurements to be performed on the single molecule. Excitation light may be delivered into the sample well 1-108, so as to excite the sample or at least one fluorescent marker attached to the sample or otherwise associated with the sample while it is within an illumination area within the sample well 1-108.

In operation, parallel analyses of samples within the sample wells 1-108 are carried out by exciting some or all of the samples within the wells using excitation light and detecting signals from sample emission with the photodetectors 1-110. Emission light from a sample may be detected by a corresponding photodetector 1-110 and converted to at least one electrical signal. The electrical signals may be transmitted along conducting lines (e.g., metal layers 1-240) of integrated device 1-102, which may be connected to an instrument and/or control circuit interfaced with the integrated device 1-102. The electrical signals may be subsequently processed and/or analyzed by the instrument and/or control circuit.

### III. Example Pixel Array Overview

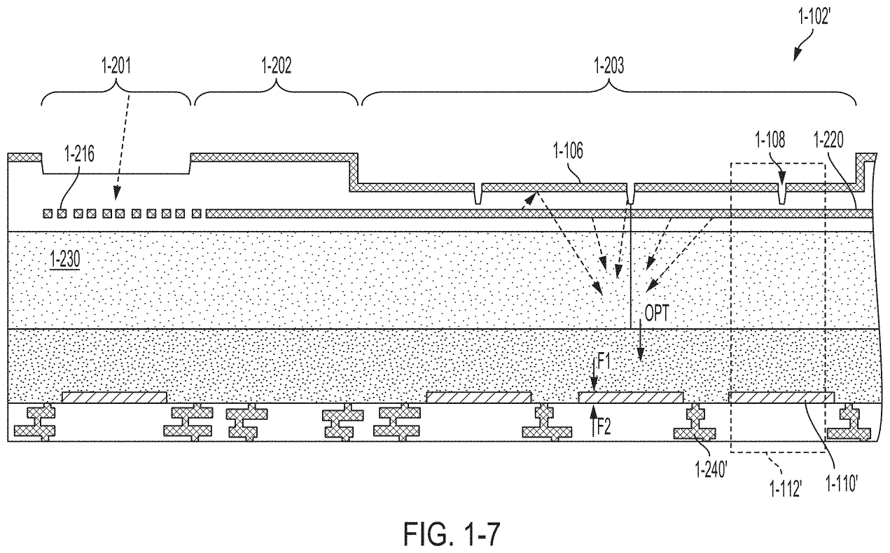

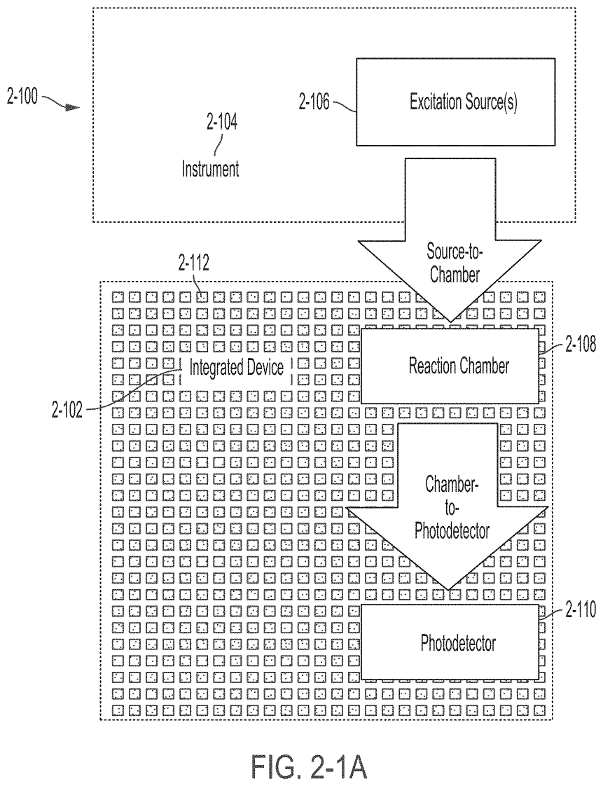

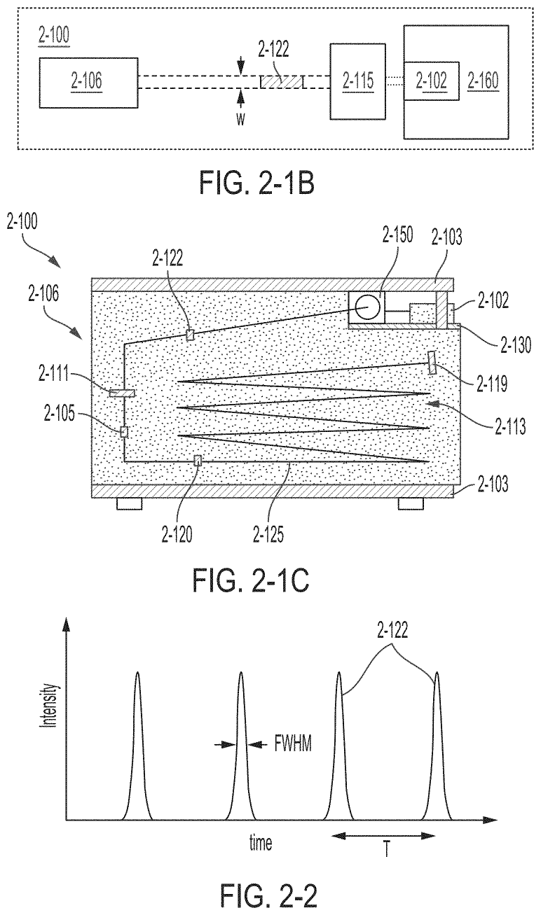

FIG. 1-2A illustrates a top view of an example pixel row 1-303 with which the inter-pixel and/or inter-photodetection region isolation concepts of the present innovation may be used but are not so limited. Pixel row 1-303 may be part of an array of pixels of example integrated device 1-102 according to one embodiment. Pixel row 1-303 includes at least two pixels 1-112 including photodetection regions, which may be pinned photodiodes (PPD1 and PPD2), at least one intermediate region IM between photodetection regions PPD1 and PPD2, drain regions D, charge storage regions, which may be storage diodes (e.g., SD0), readout regions, which may be floating diffusion (FD) regions, and transfer gates REJ, ST0, TX0, RST, SF, and RS. In some embodiments, photodetection regions PPD1 and PPD2, drain regions D, charge storage regions SD0, and/or readout region FD may be formed in the integrated device 1-102 by doping portions of one or more substrate layers of the integrated device 1-102. For example, the integrated device 1-102 may have a lightly p-doped substrate, and photodetection regions PPD1 and PPD2, drain regions D, charge storage regions SD0, and/or readout regions FD, may be n-doped regions of the substrate. In this example, p-doped regions may be doped using boron and n-doped regions may be doped using phosphorus, although other dopants and configurations are possible. In some embodiments, each pixel 1-112 may have an area smaller than or equal to 10 micrometers by 10 micrometers, such as smaller than or equal to 7.5 micrometers×5 micrometers. It should be appreciated that, in some embodiments, the substrate may be lightly n-doped and photodetection regions PPD1 and PPD2, drain regions D, charge storage regions SD0, and/or readout regions FD may be p-doped, as embodiments described herein are not so limited.

In some embodiments, photodetection regions PPD1 and PPD2 may be configured to generate charge carriers in response to incident light. For instance, during operation of pixel row 1-303, excitation light may illuminate sample well 1-108 causing incident photons, including fluorescent emissions from a sample, to flow along the optical axis OPT to photodetection regions PPD1 and/or PPD2, which may be configured to generate fluorescent emission charge carriers in response to the incident photons from sample well 1-108. In some embodiments, the integrated device 1-102 may be configured to transfer the charge carriers to drain regions D or to charge storage regions SD0. For example, during a discarding period following a pulse of excitation light, the incident photons reaching photodetection regions PPD1 and PPD2 may be predominantly excitation photons that generate noise charge carriers to be transferred to drain regions D to be discarded outside the pixel circuits. In this example, during a collection period following the discarding period, fluorescent emission photons may reach photodetection regions PPD1 and/or PPD2 to be transferred to charge storage region SD0 for collection at a later period. In some embodiments, a discarding period and collection period may follow each excitation pulse.

In some embodiments, drain regions D may be configured to receive charge carriers generated in photodetection regions PPD1 and PPD2 and/or intermediate region IM in response to the incident light. For example, drain regions D may be configured to receive charge carriers generated in or around photodetection regions PPD1 and/or PPD2 in response to excitation photons. In some embodiments, drain regions D may be electrically coupled to photodetection regions PPD1 and PPD2 by charge transfer channels. In some embodiments, the charge transfer channels may be formed by doping a region of pixel 1-112 between the pixel's photodetection region and drain region D with a same conductivity type as the photodetection region and drain region, such that the charge transfer channels are configured to be conductive when at least a threshold voltage is applied to the charge transfer channel and nonconductive when a voltage less than (or greater than, for some embodiments) the threshold voltage is applied to the charge transfer channel. In some embodiments, the threshold voltage may be a voltage above (or below) which the charge transfer channel is depleted of charge carriers, such that charge carriers from photodetection regions PPD1 and PPD2 may travel through the charge transfer channels to drain regions D. For example, the threshold voltage may be determined based on the materials, dimensions, and/or doping configuration of the charge transfer channel.

In some embodiments, transfer gates REJ may be configured to control a transfer of charge carriers from photodetection regions PPD1 and PPD2 and intermediate region IM to drain regions D. For instance, the transfer gate REJ of each pixel may be configured to receive a control signal and responsively determine a conductivity of a charge transfer channel electrically coupling the pixel's photodetection region to drain region D. For example, excitation photons from the excitation light source may reach the photodetection region before fluorescent emission photons from the sample well 1-108 reach the photodetection region. In some embodiments, the integrated device 1-102 may be configured to control transfer gates REJ to transfer charge carriers, generated in photodetection regions PPD1 and/or PPD2 in response to the excitation photons, to drain regions D during a discarding period following an excitation light pulse and preceding reception of fluorescent emission charge carriers. For example, when a first portion of a control signal is received at a pixel's transfer gate REJ, transfer gate REJ may be configured to bias the pixel's charge transfer channel below its threshold voltage (or above its threshold voltage, in some embodiments), causing the charge transfer channel to be nonconductive, such that charge carriers are blocked from reaching drain region D. Alternatively, when a second portion of the control signal is received at one or more pixels' transfer gates REJ, each transfer gate REJ may be configured to bias its charge transfer channel above its threshold voltage (or below its threshold voltage, in some embodiments) to cause the charge transfer channel to be conductive, such that charge carriers may flow from intermediate region IM and photodetection regions PPD1 and/or PPD2 to drain regions D via the charge transfer channels. In some embodiments, transfer gates REJ may be formed of an electrically conductive and at least partially opaque material such as polysilicon. In some embodiments, one or more transfer gates REJ and/or one or more charge transfer channels (e.g., controlled using transfer gate(s) REJ) may be configured as a drain device configured to cause charge carriers to flow to drain region(s) D.

In some embodiments, drain regions D may be coupled to a voltage source, such as a direct current (DC) power supply. Due to the voltage supplied to drain regions D in some embodiments, charge carriers will be drawn during a discarding period from intermediate region IM and photodetection regions PPD1 and PPD2 to drain region D.

The inventors have recognized that using a bulk semiconductor material between adjacent photodetection regions allows each photodetection region to act upon nearby charge carriers, for example, by allowing the depletion regions of the photodetection regions to extend laterally. In this manner, one or more electric fields, applied to the photodetection regions during a discarding period, can extend into the intermediate region IM between photodetection regions. In some embodiments, the bulk semiconductor material fills substantially all space between the photodetection regions. The inventors have recognized that by using a bulk semiconductor material that is no more than lightly doped in the region between adjacent photodetection regions, charge carriers located in this region can be effectively discarded. The inventors have also surprisingly discovered that the bulk semiconductor material provides sufficient isolation to prevent punch-through from one photodetector to the next at the voltages of interest for detecting fluorescence, without use of STI regions, moderately doped regions, or heavily doped regions for isolation. Thus, the example configuration shown in FIGS. 1-2A and 1-2B can be configured to quickly transfer charge carriers from photodetection regions PPD1 and PPD2 and from intermediate region IM to drain regions D.

In some embodiments, lightly doped bulk silicon is used between adjacent photodetection regions. For example, the lightly doped bulk silicon may be bulk silicon upon which no doping by ion implantation is performed. In some embodiments, the lightly doped bulk silicon is silicon as received, for example, from a wafer vendor. For example, a silicon wafer received from a wafer vendor may be lightly doped with a p-type doping. In some embodiments, the lightly doped bulk silicon may have a p-type doping in the range of 5×10¹⁴ to 5×10¹⁵ acceptors/cm³. By contrast, moderately doped semiconductor material used for isolation between photodetection regions, which the inventors have discovered inhibits the removal of noise charge carriers from such intermediate regions, would typically be doped in the range of approximately 10¹⁶ to 10¹⁹ acceptors/cm³. The doping may also be of n-type, as the invention is not so limited.

In some embodiments, transfer gate ST0 may be configured to control a transfer of charge carriers from photodetection region PPD1 to storage region SD0 in the manner described for transfer gate REJ in connection with photodetection region PPD1. Charge storage region SD0 may be configured to receive and store charge carriers generated in photodetection region PPD1 in response to fluorescent emission photons from the sample well 1-108. In some embodiments, charge storage region SD0 may be electrically coupled to photodetection region PPD1 by a charge transfer channel, formed in the manner described above in connection with the charge transfer channel coupled between drain region D and photodetection region PPD1.

In some embodiments, transfer gate TX0 may be configured to control a transfer of charge carriers from charge storage region SD0 to readout region FD in the manner described for transfer gate REJ in connection with photodetection region PPD1 and drain region D. For example, following a plurality of collection periods during which charge carriers are transferred from photodetection region PPD1 to charge storage region SD0, a readout period may occur in which charge carriers stored in charge storage region SD0 may be transferred to readout region FD to be read out to other portions of the integrated device 1-102 for processing.

In some embodiments, transfer gate RST may be configured to, in response to a reset control signal, clear charge carriers in readout region FD and/or charge storage region SD0. For example, transfer gate RST may be configured to cause charge carriers to flow from readout region FD, and/or from charge storage region SD0 via transfer gate TX0 and readout region FD, to a DC supply voltage. In some embodiments, transfer gate RS may be configured to, in response to a row select control signal, transfer charge carriers from readout region FD to a bitline for processing.

In some embodiments, pixel 1-112 may be electrically coupled to a control circuit of integrated device 1-102 and configured to receive control signals at transfer gates such as REJ, ST0, and TX0. For example, metal lines of metal layers 1-240 may be configured to carry the control signals to pixels 1-112 of the integrated device 1-102. In some embodiments, a single metal line carrying a control signal may be electrically coupled to a plurality of pixels 1-112, such as an array, subarray, row, and/or column of pixels 1-112. For example, each pixel 1-112 in an array may be configured to receive a control signal from a same metal line and/or net such that the row of pixels 1-112 is configured to drain and/or collect charge carriers from photodetection region PPD1 at the same time. Alternatively or additionally, each row of pixels 1-112 in the array may be configured to receive different control signals (e.g., row-select signals) during a readout period such that the rows read out charge carriers one row at a time.

In some embodiments, transfer gate REJ may be configured to, in response to a control signal, drain charge carriers in intermediate region IM and photodetection regions PPD1 and PPD2 to a location outside the pixel. For example, transfer gate REJ may cause charge carriers to flow from photodetection region PPD1 and drain region D to a DC power supply voltage VD.

In some embodiments, pixel row 1-303 may include second charge storage regions SD1 and transfer gates ST1 and TX1, which may be configured in the manner described herein for charge storage regions SD0 and transfer gates ST0 and TX0, respectively. For example, a pixel's charge storage regions SD0 and SD1 may be configured to receive charge carriers generated in the pixel's photodetection region (e.g., PPD1), which may be transferred to readout regions. In some embodiments, a separate readout region FD may be coupled to each charge storage region. It should be appreciated that, according to various embodiments, pixels described herein may include any number of charge storage regions.

While the transistors shown in FIG. 1-2A are field effect transistors (FETs), it should be appreciated that other types of transistors such as bipolar junction transistors (BJTs) may be used.

FIG. 1-2B is a cross sectional view of pixel row 1-303, which may be included in integrated device 1-102, according to some embodiments, as viewed across the A-A′ axis depicted in FIG. 1-2A. In the embodiment depicted in FIG. 1-2B, photodetection regions PPD1 and PPD2 are positioned along a surface U. Intermediate region IM is composed of bulk semiconductor material and is positioned along surface U and between photodetection regions PPD1 and PPD2. In some embodiments, surface U may be a pinning layer. In some embodiments, surface U may be contiguous across PPD1 and PPD2. In some embodiments, surface U may be above photodetection regions PPD1 and PPD2 and intermediate region IM when the photodetection regions are part of pixels 1-112 and oriented as depicted in FIG. 1-1. In some embodiments, photodetection regions PPD1 and PPD2 and intermediate region IM are positioned underneath and abutting surface U. In some embodiments, intermediate region IM fills substantially all space between photodetection regions PPD1 and PPD2, as depicted in FIG. 1-2B. In some embodiments, there may be no STI or region of moderately or heavily doped material between photodetection regions PPD1 and PPD2. In some embodiments, as depicted in FIG. 1-2B, intermediate region IM may extend in a direction normal to the surface of pinning layer U at least as far as photodetection regions PPD1 and PPD2 extend in that direction. In some examples, intermediate region IM may extend downwards at least as far as the lowermost extremity of photodetection regions PPD1 and PPD2. In some embodiments, pixel row 1-303 contains many photodetection regions, and an intermediate region IM is positioned between each adjacent pair of photodetection regions.

The inventors have appreciated that following the techniques described herein increases the rate of charge transfer in a pixel and thereby improves signal detection. Increasing the rate of charge transfer in a pixel can improve the noise performance of the pixel, as described further herein. For instance, it can be desirable to drain as many excitation charge carriers generated in and around the photodetection regions in response to excitation photons as possible before fluorescent emission charge carriers reach the pixels, to prevent the excitation charge carriers from being transported to the charge storage region as noise. Moreover, it can be desirable to transport fluorescent emission charge carriers generated in the photodetection regions in response to fluorescent photons to the appropriate charge storage region as quickly as possible to ensure the accuracy of charge readouts from the pixel.

In some embodiments, pixels 1-112 of integrated device 1-102 may include one or more drain layers configured to receive incident photons and/or charge carriers via the photodetection regions. For example, incident photons and/or charge carriers generated in photodetection regions may flow to the drain layers via the photodetection regions (and/or along paths other than through the photodetection regions). As shown in FIG. 1-2B, pixel 1-112 includes drain layers DL positioned after photodetection region PPD1 along the optical axis OPT, in which photodetection region PPD1 is configured to receive incident photons.

In some embodiments, drain layers DL may be configured to discard received charge carriers and/or charge carriers generated in drain layers DL in response to received incident photons. For example, drain layers DL are shown in FIG. 1-2B including a protection layer PRO and a collection layer COL1. In some embodiments, collection layer COL1 may be configured to discard received charge carriers and/or charge carriers generated in collection layer COL1 response to receiving the incident photons. For example, collection layer COL1 may be configured for coupling to a DC power supply voltage (e.g., a high voltage for discarding electrons or a low voltage for discarding holes). In some embodiments, collection layer COL1 may formed in integrated device 1-102 by doping portions of substrate layer SUB with the same conductivity type as photodetection region PPD1. For instance, photodetection region PPD1 and collection layer COL1 may include n-type doped regions formed of and/or disposed on one or more lightly p-doped substrate layers SUB of integrated device 1-102.

In some embodiments, drain layers DL may be configured to block at least some charge carriers from leaving photodetection region PPD1. For example, protection layer PRO may be configured to block at least some charge carriers from reaching collection layer COL1 via photodetection region PPD1. As shown in FIG. 1-2B, protection layer PRO may be disposed between photodetection region PPD1 and collection layer COL1 in along the optical axis OPT. In some embodiments, protection layer COL may be configured to form a potential barrier between photodetection region PPD1 and collection layer COL1. For example, protection layer PRO may have an opposite semiconductor doping type from photodetection region PPD1 and/or collection layer COL1. For instance, in the above example, the protection layer PRO may be p-type doped. By blocking charge carriers from leaving photodetection region PPD1, the charge carriers may be routed to drain region D or a charge storage region, as appropriate.

In some embodiments, integrated device 1-102 may include one or more barriers configured to block at least some noise charge carriers from reaching charge storage region SD0 and/or to block incident photons from reaching charge storage region SD0 (and/or other areas of pixels 1-112 such as other charge storage regions and/or readout region FD) and generating noise charge carriers. For example, pixels 1-112 may include one or more optical barriers comprising at least partially opaque material. Alternatively or additionally, pixels 1-112 may include one or more electrical barriers (e.g., doped regions comprising an opposite conductivity type from charge storage region SD0).

FIG. 1-3A is a partial schematic of pixel row 1-303 further illustrating a plurality of contacts 1-310a, 1-310b, and 1-310c, according to some embodiments. FIG. 1-3B is a side view of a cross-section of pixel row 1-303, according to some embodiments as viewed across the B-B′ axis depicted in FIG. 1-3A. As shown in FIG. 1-3B, pixel 1-112 may further include a Buried P-Well (BPW) barrier and a Low threshold voltage P-Well (LPW) barrier. In some embodiments, barriers BPW and LPW may be doped with an opposite conductivity type from photodetection region PPD1 and/or charge storage region SD0. Also shown in FIG. 1-3B, drain layers DL may further include another collection layer COL2, which may be configured in like manner as collection layer COL1.

In some embodiments, contacts 1-310a, 1-310b, and 1-310c, may be configured to block incident photons from reaching charge storage region SD0. For example, contacts 1-310a, 1-310b, and 1-310c, may comprise an at least partially opaque material, such as a metal (e.g., tungsten). As shown in FIGS. 1-3B, contacts 1-310a and 1-310b are elongated substantially parallel to the direction of incident light (e.g., optical axis OPT), so as to block off-axis incident light (e.g., along off-axis OPT′) from reaching charge storage region SD0. Also shown in FIGS. 1-3B, contacts 1-310a and 1-310b are elongated from a metal layer METAL1 toward photodetection region PPD1. In some embodiments, one or more contacts may be elongated from a metal layer to a transfer gate, such as shown for via 1-314. For example, via 1-314 could be repositioned (e.g., as indicated by dotted box 1-314′) to additionally block incident photons from reaching charge storage region SD0.

In some embodiments, contacts 1-310a, 1-310b, and 1-310c may be elongated across multiple pixels in a pixel row and/or between pixel rows to block off-axis incident photons from crossing between adjacent pixel rows. For example, as shown in FIG. 1-3A, contacts 1-310a, 1-310b, and 1-310c, are elongated, substantially in the illustrated row direction, across multiple pixels 1-112 in pixel row 1-303. Also shown in FIGS. 1-3A, contacts 1-310a and 1-310c may separate pixel 1-112 from pixels in adjacent pixel rows (not shown), with contact 1-310a blocking incident photons from reaching charge storage and/or readout regions of a first adjacent pixel row and with contact 1-310c blocking incident photons from a second adjacent pixel row from reaching charge storage region SD0 and readout region FD.

In some embodiments, the contacts may be electrically isolated from photodetection region PPD1. For example, contacts 1-310a and 1-310b may be elongated from a metal layer METAL1 to photodetection region PPD1 without physically contacting photodetection region PPD1. As shown in FIG. 1-3B, pinning layer U may be positioned between contacts 1-310a and 1-310b and photodetection region PPD1.

In some embodiments, collection layer COL2 may be configured to discard received charge carriers, such as described herein for collection layer COL1. For example, collection layer COL2 may be configured to discard any noise charge carriers that would otherwise flow toward charge storage region SD0 and/or readout region FD.

In some embodiments, barriers BPW and LPW may be configured to block charge carriers from reaching charge storage region SD0 and/or readout region FD via undesired paths (e.g., paths other than charge transfer channels that may be controlled using transfer gates). For example, as shown in FIG. 1-3B, barrier BPW is positioned, at least in part, between collection layer COL2 and charge storage region SD0, and barrier LPW is positioned, at least in part, between collection layer COL2 and readout region FD. In some embodiments, a Deep P-Implant (DPI) barrier may be positioned, at least in part, between photodetection region PPD1 and charge storage region SD0, such as elongated parallel to the optical axis from protection layer PRO to barrier BPW (e.g., adjacent collection layer COL2.

In some embodiments, pixels 1-112 of integrated device 1-102 may include photodetection regions configured to induce an intrinsic electric field in a direction from the photodetection region to the drain region and/or a charge storage region.

The inventors recognized it can be advantageous to induce an intrinsic electric field in the photodetection region of a pixel for the photodetection region to have a high charge transfer rate for charge carriers transferred out from the photodetection region and/or intermediate region to the appropriate location in the pixel (e.g., drain region or charge storage region).

FIG. 1-4 is a magnified schematic of photodetection region PPD1 of pixel 1-112, according to some embodiments. In some embodiments, photodetection region PPD1 may be configured to induce an intrinsic electric field in a charge transfer direction Qdir from photodetection region PPD1 to the drain region D and/or charge storage region SD0. For example, the intrinsic electric field may exert a force (e.g., in the charge transfer direction Qdir) that causes charge carriers to travel more quickly from photodetection region PPD1 to the drain region D and/or charge storage region SD0 than without the intrinsic electric field. In some embodiments, drain region D and charge storage region SD) may be positioned on a same side of the photodetection region (e.g., in the charge transfer direction Qdir), such that the intrinsic electric field may increase the rate of charge transfer to each of the drain and charge storage regions.

In some embodiments, photodetection region PPD1 may include a dopant pattern configured to induce the intrinsic electric field. For example, the dopant pattern of photodetection region PPD1 may have a first end and a second end, with the first end being wider than the second end. As shown in FIG. 1-4, photodetection region PPD1 has a dopant pattern with a first end E1 spaced from a second end E2 substantially in the direction Qdir of charge carrier transfer from photodetection region PPD1 to drain region D and charge storage region SD0. In some embodiments, the dopant pattern of photodetection region PPD1 may have a higher dopant concentration at first end E1 (e.g., proximate drain region D and charge storage region SD0) than at second end E2, thereby causing a potential gradient from first end E1 to second end E2. For example, as shown in FIG. 1-4, the dopant configuration of photodetection region PPD1 is wider, in a direction Wdir perpendicular to the optical axis OPT and the charge carrier transfer direction Qdir, at first end E1 than at second end E2. In some embodiments, the dopant configuration may be at least 75% wider at first end E1 than at second end E2. In some embodiments, the dopant configuration may be at least 90% wider at first end E1 than at second end E2. As shown in FIG. 1-4, the dopant configuration has a substantially triangular shape, with the base of the triangle positioned at first end E1 and the apex corresponding to the base positioned at second end E2.

In some embodiments, the dopant pattern of photodetection region PPD1 may be formed by placing a mask with a shaped opening over photodetection region PPD1 during at least a portion of doping of photodetection region PPD1. For example, photodetection region PPD1 may be formed by doping photodetection region PPD1 via the mask. As shown in FIG. 1-4, pixel 1-112 has a mask M having an opening 0 surrounding the dopant configuration of photodetection region PPD1. For example, mask M may include a thin, at least partially opaque and at least partially insulative material. In some embodiments, mask M may have a thickness of less than 1 micron, such as 0.6 microns, in a direction parallel to the optical axis OPT. In some embodiments, opening 0 may have a first end and a second end, with the first end being wider than the second end. For instance, as shown in FIG. 1-4, opening 0 has a first end positioned at first end E1 and a second end positioned at second end E2, with opening 0 being wider at first end E1 than at the second end E2. In some embodiments, opening 0 may be at least 75% wider at first end E1 than at second end E2. In some embodiments, opening 0 may be at least 90% wider at first end E1 than at second end E2. For example, as shown in FIG. 1-4, opening 0 has a substantially triangular shape, with the base of the triangle positioned at first end E1 and the apex corresponding to the base positioned at second end E2. In some embodiments, at least a portion of photodetection region PPD1 may be manufactured by depositing mask M above and/or below a portion of photodetection region PPD1 and removing at least a portion of mask M to create opening 0, such that opening 0 is wider at first end E1 than at second end E2.

The inventors have recognized that, by inducing an intrinsic electric field in the photodetection region, the rate at which charge carriers are transferred out from the photodetection region may be increased, thereby decreasing the number of excitation photons and increasing the number of fluorescent emission photons that reach the charge storage region(s), and resulting in an increase in the signal to noise ratio of charge readouts from the pixel. Increasing the rate of charge carrier transport in the pixel increases the fluorescence-to-excitation rejection ratio of the pixel by discarding excitation charge carriers faster and accumulating more fluorescent emission charge carriers in the charge storage region(s). As a result, the ratio of fluorescent emission signals to excitation noise may be improved for more accurate measurement of fluorescent information.

FIG. 1-5 is a partial schematic of an alternative row of pixels 1-503 that may be included in integrated device 1-102, according to some embodiments. In some embodiments, pixel row 1-503 may be configured in the manner described herein for pixel row 1-303. For example, as shown in FIG. 1-5, pixel row 1-503 includes pixels 1-512 with intermediate regions IM between photodetection regions of adjacent pixels 1-512 in the row direction. In some embodiments, pixels 1-512 may be configured in the manner described herein for pixel 1-112. For example, as shown in FIG. 1-5, pixel 1-512 includes photodetection region PPD1, charge storage region SD0, drain region D, readout region FD, and transfer gates REJ, ST0, TX0, RST, SF, and RS. Also shown in FIG. 1-5, pixel 1-512 includes contacts 1-520a, 1-520b, and 1-520c, which may be configured in the manner described herein for contacts 1-312a, 1-312b, and 1-312c, respectively. In some embodiments, pixels of integrated device 1-102 may have multiple storage regions and multiple transfer gates controlling transfer of charge carriers to a charge storage region and/or to readout region FD. For example, as shown in FIG. 1-5, pixel 1-512 includes a second charge storage region SD1 and transfer gate ST1.

In some embodiments, charge storage regions of integrated device 1-102 may be configured to induce a potential gradient from the photodetection region through the charge storage regions. For example, the photodetection region, charge storage region(s), and/or readout region may have different intrinsic electric potential levels, such as due to different dopant concentrations. In some embodiments, photodetection region PPD1 may have a first dopant concentration, charge storage region SD0 may have a second dopant concentration higher than the first dopant concentration, and readout region RF may have a higher dopant concertation than the second dopant concentration. Alternatively or additionally, charge storage region SD1 may have a third dopant concentration higher than the second dopant concentration, and readout region may have a higher dopant concentration than the third dopant concentration. In embodiments in which photodetection region PPD1, charge storage regions SD0 and SD1, and readout region FD are n-type doped, the intrinsic electric potential level may increase from photodetection region PPD1 to readout region FD, resulting in a high charge transfer rate from photodetection region PPD1 to readout region FD via charge storage regions SD0 and SD1

In some embodiments, charge storage regions of integrated device 1-102 may have sub-regions having different intrinsic electric potential levels so as to contribute to the potential gradient. As shown in FIG. 1-5, charge storage region SD1 has multiple sub-regions SD1-0 and SD1-1. In some embodiments, sub-region SD1-1 and sub-region SD1-0 may have different intrinsic electrical potential levels. For example, sub-region SD1-1 may have a higher dopant concentration than sub-region SD1-0.

In some embodiments, pixel 1-512 may be operable to collect charge carriers in charge storage region SD0 over the course of one or more excitations of a sample (e.g., in sample well 1-08), transfer the collected charge carriers to charge storage region SD1, and then resume collecting charge carriers in charge storage region SD0 over the course of one or more subsequent excitations of the sample. Transferring collected charge carriers from charge storage region SD0 to charge storage region SD1 between excitations of the sample allows charge storage region SD0 to resume collection of charge carriers while the previously collected charge carriers wait to be read out (e.g., as the array of pixels is read out row by row, column by column, and/or pixel by pixel), resulting in quick and efficient sample measurements.

FIG. 1-6A is a partial schematic of a further alternative row of pixels 1-603 that may be included in integrated device 1-102, according to some embodiments. In some embodiments, pixel row 1-603 may be configured in the manner described herein for pixel row 1-303. For example, as shown in FIG. 1-6A, pixel row 1-603 includes pixels 1-612a, 1-612b, 1-612c, and 1-612d, with intermediate regions IM between photodetection regions of adjacent pixels in the row direction. In some embodiments, pixels 1-612a, 1-612b, 1-612c, and 1-612d may be configured in the manner described herein for pixel 1-112. For example, as shown in FIG. 1-6A, pixel 1-612a includes photodetection region PPD1, transfer gates REJ, ST0, TX0, RST, SF, and RS, as well as contacts 1-620a, 1-620b, and 1-620c, which may be configured in the manner described herein for contacts 1-310a, 1-310b, and 1-310, respectively. In some embodiments, pixels 1-612a, 1-612b, 1-612c, and 1-612d may be configured in the manner described herein for pixel 1-512. For example, as shown in FIG. 1-6A, pixel 1-612a includes charge storage region SD1, including sub-regions SD1-0 and SD1-1, and transfer gate ST1. Pixels 1-612b, 1-612c, and 1-612d are shown in FIG. 1-6A including photodetection regions PPD2, PPD3, and PPD4, respectively.

In some embodiments, integrated device 1-102 may include a mirrored arrangement of pixels. For example, pixels of integrated device 1-102 may be mirrored with respect to adjacent pixels (e.g., in the row direction) such that components of each pixel are positioned adjacent like components of adjacent pixels. As shown in FIG. 1-6A, charge storage region SD0, readout region FD, and transfer gates ST0, TX0, and RST of pixel 1-612a are positioned adjacent charge storage region SD0, readout region FD, and transfer gates ST0, TX0, and RST, respectively, of adjacent pixel 1-612b in pixel row 1-603. Similarly, as shown in FIG. 1-6A, drain region D and transfer gates REJ and RS are positioned adjacent drain region D and transfer gates REJ and RS, respectively, of adjacent pixel 1-612c in pixel row 1-603. Using mirrored arrangements of pixels, in the row direction, facilitates having control signal lines of an integrated device each connect to multiple adjacent pixels in the row direction.

FIG. 1-6A further illustrates metal lines connected to pixels 1-612a, 1-612b, 1-612c, and 1-612d, according to some embodiments. As shown in FIG. 1-6A, the metal lines of integrated device 1-102 include control signal lines VREJ and VST0 and power supply voltage lines VDDP. It should be appreciated that integrated device 1-102 may include additional metal lines not shown in FIG. 1-6A.

In some embodiments, control signal lines VREJ and VST0 may be configured to carry control signals for controlling transfer gates REJ and ST0, respectively. In some embodiments, power supply voltage lines VDDP may be configured to discard charge carriers transferred to drain regions D and/or reset the sampling voltage in readout regions FD and bias the semiconductor regions adjacent transfer gate SF.

In some embodiments, metal lines of integrated device 1-102 may be configured for connecting to multiple adjacent pixels in the row direction. Using metal lines connecting to multiple adjacent pixels, in the row direction, allows the metal lines to be made wide and spaced far apart, providing low capacitance between adjacent metal lines, resulting in low skew in signals carried by the metal lines.

As shown in FIG. 1-6A, control signal line VREJ is positioned between adjacent pixels 1-612a and 1-612b. In some embodiments, control signal line VREJ may be configured for connecting to transfer gates REJ of pixels 1-612a, 1-612b, and 1-612c. For example, as shown in FIG. 1-6A, control signal line VREJ connects to transfer gates REJ of pixels 1-612a and 1-612b by metal portions 1-630a and 1-640a. In some embodiments, control signal line VREJ may further connect to transfer gate REJ of pixel 1-612c via transfer gate REJ of pixel 1-612a. For example, transfer gates REJ of pixels 1-612a and 1-612c may be electrically connected together at the transfer gate level of integrated device 1-102, such as by polysilicon components of the transfer gates. Although not shown, it should be appreciated that transfer gate REJ of pixel 1-612d may be configured to connect to a control signal line VREJ via a transfer gate REJ of an adjacent pixel (not shown) in pixel row 1-603. Similarly, a transfer gate REJ of a pixel (not shown) adjacent pixel 1-612b along pixel row 1-603 may be configured to connect to the illustrated control signal line VREJ via transfer gate REJ of pixel 1-612b.

FIG. 1-6B is a side view of a cross-section of pixel row 1-603, according to some embodiments, as viewed across the C-C′ axis depicted in FIG. 1-6A. As shown in FIG. 1-6B, control line VREJ is disposed on a third metal layer METAL3. Also shown in FIG. 1-6B, a via 1-614 connects control signal line VREJ to metal portion 1-630a, which is shown disposed on a second metal layer METAL2 between first metal layer METAL1 and third metal layer METAL3.

Also shown in FIG. 1-6B, a via 1-614 connects metal portion 1-630a to metal portion 1-640a, which is shown disposed on first metal layer METAL1. Also shown in FIG. 1-6B, metal portion 1-640a is connected to transfer gate REJ of pixel 1-612a by a via 1-614. While not shown, it should be appreciated that control signal line VREJ may connect to transfer gate REJ of pixel 1-612b in like manner.

Returning to FIG. 1-6A, control signal line VST0 is shown positioned between adjacent pixels 1-612c and 1-612d. In some embodiments, control signal line VST0 may be configured for connecting to transfer gates ST0 of pixels 1-612a, 1-612b, 1-612c, and 1-612d. For example, as shown in FIG. 1-6A, control signal line VST0 is connected to transfer gates ST0 of pixels 1-612a and 1-612d by metal portions 1-630b and 1-640b. In some embodiments, control signal line VST0 may further connect to transfer gate ST0 of pixels 1-612b and 1-612c via transfer gates ST0 of pixels 1-612a and 1-612d, respectively. For example, transfer gates ST0 of pixels 1-612a and 1-612b may be electrically connected together at the transfer gate level of integrated device 1-102, such as by polysilicon components of the transfer gates, and transfer gates ST0 of pixels 1-612c and 1-612d may be electrically connected in like manner.

FIG. 1-6C is a side view of a cross-section of pixel row 1-603, according to some embodiments, as viewed across the D′-D″ axis depicted in FIG. 1-6A. As shown in FIG. 1-6C, a via 1-614 connects metal portion 1-640b, shown disposed on first metal layer METAL1, to transfer gate ST0 of pixel 1-612a. Metal portion 1-640b further connects to metal portion 1-630b (FIG. 1-6A), which may be disposed on second metal layer METAL2 and connected by a via to control line VST0 disposed on third metal layer METAL3. While not shown in FIG. 1-6C, it should be appreciated that control signal line VST0 may connect to transfer gate ST0 of pixel 1-612d in like manner.

Returning again to FIG. 1-6A, a power supply voltage line VDDP is shown positioned between adjacent pixels 1-612a and 1-612c. In some embodiments, power supply voltage lines VDDP may be configured for connecting to drain regions D and regions adjacent transfer gates SF by one or more metal layers, such as described herein for control signal lines VREJ and VST0.

While FIGS. 1-6A, 1-6B, and 1-6C show pixels having multiple charge storage regions, it should be appreciated that pixels having any number of charge storage regions may be positioned in mirrored arrangements and/or have metal lines connecting to multiple adjacent pixels, as embodiments described herein are not so limited. For example, pixels 1-112 may be positioned in a mirrored arrangement.

FIG. 1-7 is a partial schematic of an alternative integrated device 1-102′, according to some embodiments. In some embodiments, integrated device 1-102′ can be configured in the manner described herein for integrated device 1-102. For example, as shown in FIG. 1-7, integrated device 1-102′ can include coupling region 1-201 including one or more grating couplers 1-216, routing region 1-202 including one or more waveguides 1-220, and pixel region 1-203 including one or more pixels 1-112′. An example pixel 1-112′ is indicated by a dotted box in FIG. 1-7 including a sample well 1-108 and a photodetector 1-110′. Also shown in FIG. 1-7, integrated device 1-102′ can include one or more photonic structures 1-230 positioned between sample wells 1-108 and photodetectors 1-110′.

In some embodiments, photodetector 1-110′ may be configured to receive incident photons at a first side F1, and metal layers 1-240′ may be positioned on a second side F2 of photodetector 1-110′ that is opposite first side F1 along the optical axis OPT in which photodetector 1-110′ is configured to receive incident photons. For example, the photodetection region of pixel 1-112′ may be configured to receive incident photons at a first side of photodetection region (e.g., at F1) and metal lines and transfer gates of integrated device 1-102′ may be positioned at a second, opposite side of the photodetection region (e.g., at F2). In this example, charge storage regions, drain regions, charge transfer channels, and/or transfer gates may be positioned at the second side of the photodetection region. For instance, a drain device (e.g., including a drain transfer gate and drain transfer channel) may be positioned at the second side of the photodetection region. In some embodiments, integrated device 1-102′ can have a backside-illuminated (BSI) configuration. It should be appreciated that any or all techniques described herein may be alternatively or additionally implemented in integrated device 1-102′, as embodiments are not so limited.

### IV. DNA, RNA, and Protein Sequencing Applications

An analytic system described herein may include an integrated device and an instrument configured to interface with the integrated device, for example a biological sequencing instrument. As described above, the integrated device may include an array of pixels, where a pixel includes a sample well and at least one photodetector. A sample well may be configured to receive a sample from a suspension placed on the surface of the integrated device.

Some aspects of the present disclosure may be useful for DNA or RNA sequencing. In some embodiments, a suspension may contain multiple single-stranded DNA templates. The suspension may also contain labeled nucleotides which then enter in the reaction chamber and may allow for identification of a nucleotide as it is incorporated into a strand of DNA complementary to the single-stranded DNA template in the reaction chamber.

Some aspects of the present disclosure may be useful for protein sequencing, such as determining amino acid sequence information from polypeptides. In some embodiments, amino acid sequence information can be determined for single polypeptide molecules. In some embodiments, one or more amino acids of a polypeptide are labeled, and the relative positions of the labeled amino acids in the polypeptide are determined, for example using a series of amino acid labeling and cleavage steps. In some embodiments, the identities of amino acids are assessed. Some aspects of the present disclosure provide a method of sequencing a polypeptide by detecting luminescence of a labeled polypeptide which is subjected to repeated cycles of terminal amino acid modification and cleavage.

In some embodiments, methods provided herein may be used for the sequencing and identification of an individual protein in a sample comprising a complex mixture of proteins. Sequencing in accordance with some embodiments can involve immobilizing a polypeptide on a surface of a substrate or solid support, such as a chip or integrated device. In some embodiments, a polypeptide can be immobilized on a surface of a sample well on a substrate. In some embodiments, each of a plurality of polypeptides is attached to one of a plurality of sample wells, for example in an array of sample wells on a substrate.

A schematic overview of a system 2-100 is illustrated in FIG. 2-1A. The system comprises both an integrated device 2-102 that interfaces with an instrument 2-104. In some embodiments, integrated device 2-102 may be configured in similar manner to integrated device 1-102 and/or 1-102′, described above. In some embodiments, instrument 2-104 may include one or more excitation sources 2-106 integrated as part of instrument 2-104. The excitation source 2-106 may be configured to provide excitation light to the integrated device 2-102. As illustrated schematically in FIG. 2-1A, the integrated device 2-102 has a plurality of pixels 2-112 arranged in an array having rows and columns, where at least a portion of pixels may perform independent analysis of a sample of interest. A pixel 2-112 has a sample well or reaction chamber 2-108 configured to receive a single sample of interest and a photodetector 2-110 for detecting emission light emitted from the reaction chamber in response to illuminating the sample and at least a portion of the reaction chamber 2-108 with excitation light provided by the excitation source 2-106.

Integrated device 2-102 may have any suitable number of pixels. In some embodiments, the number of pixels in integrated device 2-102 may be in the range of approximately 10,000 pixels to 100,000,000 pixels or any value or range of values within that range. The interface of instrument 2-104 may position integrated device 2-102 to couple with circuitry of instrument 2-104 to allow for readout signals from one or more photodetectors to be transmitted to instrument 2-104. Integrated device 2-102 and instrument 2-104 may include multi-channel, high-speed communication links for handling data associated with large pixel arrays (e.g., more than 10,000 pixels).

In some embodiments, pixels 2-112 may be configured in like fashion to pixel 1-112, 1-512, and/or 1-612a described above. Alternatively or additionally, integrated device 2-102 may be configured in the manner described herein for integrated device 1-102′, with pixels 2-112 configured in like fashion to pixel 1-112′. Excitation light may illuminate a sample located within a sample well or reaction chamber. When in an excited state, the sample may emit emission light, which may be detected by one or more photodetectors associated with the reaction chamber.

Instrument 2-104 may include a user interface for controlling operation of instrument 2-104 and/or integrated device 2-102. The user interface may be configured to allow a user to input information into the instrument, such as commands and/or settings used to control the functioning of the instrument. In some embodiments, instrument 2-104 may include a computer interface configured to connect with a computing device, such as a laptop or desktop computer or a server.

The computer interface may be a USB interface, a FireWire interface, or any other suitable computer interface. The computing device may send and/or receive via the computer interface input information for controlling or configuring the instrument 2-104 and/or output information generated by instrument 2-104.

Referring to FIG. 2-1B, a portable, advanced analytic instrument 2-100 can comprise one or more pulsed optical sources 2-106 mounted as a replaceable module within, or otherwise coupled to, the instrument 2-100. The portable analytic instrument 2-100 can include an optical coupling system 2-115 and an analytic system 2-160 including integrated device 2-102. The optical coupling system 2-115 can be configured to couple output optical pulses 2-122 from the pulsed optical source 2-106 to the integrated device 1-102 of analytic system 2-160. The integrated device 1-102 of the analytic system 2-160 can direct the optical pulses to at least one sample well or reaction chamber 2-108 for sample analysis, receive one or more optical signals (e.g., fluorescence, backscattered radiation) from the at least one sample well or reaction chamber 2-108, and produce one or more electrical signals representative of the received optical signals. For example, the analytic system 5-160 can include one or more photodetectors 2-110 of integrated device 1-102 and may also include signal-processing electronics. The analytic system 2-160 can also include data transmission hardware configured to transmit and receive data to and from external devices.

FIG. 2-1C depicts a further example of a portable analytical instrument 2-100 that includes a compact pulsed optical source 2-113. The analytic instrument may be configured to receive integrated device 2-102. In some cases, integrated device 2-102 may be and/or include a removable, packaged, bio-optoelectronic or optoelectronic chip. The chip can contain, for example, sample wells or reaction chambers 2-108, integrated optical components (e.g., 1-201 and 1-202, FIG. 1-1) arranged to deliver optical excitation energy to the sample wells or reaction chambers 2-108, and integrated photodetectors 2-110 arranged to detect fluorescent emission from the sample wells or reaction chambers 2-108. In some implementations, the chip can be disposable after a single use.

In some embodiments, integrated device 2-102 can be mounted on an electronic circuit board 2-130 that can include additional instrument electronics. For example, the PCB 2-130 can include circuitry configured to provide electrical power, one or more clock signals, and control signals to integrated device 2-102, and signal-processing circuitry arranged to receive signals representative of fluorescent emission detected from the sample wells or reaction chambers 2-108. Data returned from integrated device 2-102 can be processed in part or entirely by electronics on the instrument 2-100, although data may be transmitted via a network connection to one or more remote data processors, in some implementations.

FIG. 2-2 depicts temporal intensity profiles of the output pulses 2-122, though the illustration is not to scale. In some embodiments, the peak intensity values of the emitted pulses may be approximately equal, and the profiles may have a Gaussian temporal profile, though other profiles such as a sech2 profile may be possible. The duration of each pulse may be characterized by a full-width-half-maximum (FWHM) value, as indicated in FIG. 2-2. According to some embodiments of a mode-locked laser, ultrashort optical pulses can have FWHM values between approximately 5 picoseconds (ps) and approximately 30 ps.

The output pulses 2-122 can be separated by regular intervals T. For example, T can be determined by a round-trip travel time between the output coupler 2-111 and cavity end mirror 2-119. In some embodiments, the pulse-separation interval corresponds to a round trip travel time in the laser cavity, so that a cavity length of 3 meters (round-trip distance of 6 meters) provides a pulse-separation interval T of approximately 20 ns.

In some embodiments, different fluorophores can be distinguished by their different fluorescent decay rates or characteristic lifetimes. Accordingly, in certain embodiments pulse-separation interval T is sufficient to collect adequate statistics for the selected fluorophores to distinguish between their different decay rates. Adequate pulse-separation interval T enables data handling circuitry to process the data collected by the reaction chambers. In some embodiments, pulse-separation interval T between about 5 ns and about 20 ns is generally suitable for fluorophores that have decay rates up to about 2 ns and for handling data from between about 60,000 and 32,000,000 reaction chambers. In some embodiments, data handling circuitry can process data from up to 100,000,000 reaction chambers.

Having thus described several aspects and embodiments of the technology of the present disclosure, it is to be appreciated that various alterations, modifications, and improvements will readily occur to those of ordinary skill in the art. Such alterations, modifications, and improvements are intended to be within the spirit and scope of the technology described herein. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. The transitional phrases “consisting of” and “consisting essentially of” shall be closed or semi-closed transitional phrases, respectively.

The terms “approximately,” “substantially,” and “about” may be used to mean within ±20% of a target value and/or aspect in some embodiments, within ±10% of a target value in some embodiments, within ±5% of a target value in some embodiments, and yet within ±2% of a target value in some embodiments. The terms “approximately,” “substantially,” and “about” may include the target value.

What is claimed is:

1. An integrated circuit, comprising:
a surface;
a first photodetection region;
a second photodetection region; and
an intermediate region situated between the first and second photodetection regions, wherein the first and second photodetection regions and the intermediate region are positioned along the surface, and wherein the intermediate region comprises bulk semiconductor material.

2. The integrated circuit of claim 1, wherein the intermediate region extends in a direction away from the surface at least as far as the furthermost extremity of the first and second photodetection regions in the direction away from the surface.

3. The integrated circuit of claim 1, wherein the intermediate region is no more than lightly doped.

4. The integrated circuit of claim 1, wherein the surface is continuous from the first to the second photodetection region.

5. The integrated circuit of claim 1, wherein the intermediate region occupies substantially all space between the first and second photodetection regions.

6. The integrated circuit of claim 1, further comprising a pixel comprising the first photodetection region, wherein the pixel has an area smaller than or equal to 7.5 micrometers×5 micrometers.

7. The integrated circuit of claim 1, further comprising:
a first drain region; and
a first drain device electrically coupled to the first photodetection region, wherein the first drain device and the intermediate region are configured to cause charge carriers to flow from the intermediate region to the first drain region.

8. The integrated circuit of claim 7, further comprising:
a drain transfer gate electrically coupled to the first drain device and configured to control a transfer of charge carriers from at least the first photodetection region to the first drain region.

9. An integrated circuit, comprising:
a first photodetection region;
a second photodetection region;
an intermediate region between the first and second photodetection regions;
a first drain region; and
a first drain device electrically coupled to the first photodetection region, wherein the first drain device and the intermediate region are configured to cause charge carriers to flow from the intermediate region to the first drain region.

10. The integrated circuit of claim 9, further comprising:
a second drain region; and
a second drain device electrically coupled to the second photodetection region, wherein the second drain device and the intermediate region are configured to cause charge carriers to flow from the intermediate region to the second drain region.

11. The integrated circuit of claim 10, wherein the first and second drain devices and the intermediate region are configured to cause substantially all charge carriers located in the intermediate region to flow to the first and/or second drain regions.

12. The integrated circuit of claim 9, further comprising:
a drain transfer gate electrically coupled to the first drain device and configured to control a transfer of charge carriers from at least the first photodetection region to the first drain region.

13. The integrated circuit of claim 9, wherein there is no trench isolation separating the first and second photodetection regions.

14. The integrated circuit of claim 9, wherein there is no heavily doped region situated between the first and second photodetection regions.

15. The integrated circuit of claim 12, further comprising a pixel comprising the first photodetection region and the first drain region, wherein the pixel has an area smaller than or equal to 7.5 micrometers×5 micrometers.

16. The integrated circuit of claim 9, wherein:
the first photodetection region is configured to receive incident photons at a first side of the first photodetection region; and
the drain device is positioned at a second side of the first photodetection region that is opposite the first side.

17. A method of manufacturing an integrated circuit, the method comprising:
forming a surface;
forming a first photodetection region;
forming a second photodetection region; and
forming an intermediate region situated between the first and second photodetection regions, wherein the first and second photodetection regions and the intermediate region are positioned along the surface, wherein the intermediate region comprises bulk semiconductor material, and wherein in the integrated circuit, as manufactured, the intermediate region abuts the surface.

18. The method of claim 17, further comprising:
forming a first drain region of the integrated circuit;
forming a first drain device electrically coupled to the first photodetection region, wherein the first drain device is configured to cause charge carriers to flow from the intermediate region to the first drain region.

19. The method of claim 17, wherein forming the first photodetection region includes doping the first photodetection region, wherein forming the second photodetection region includes doping the second photodetection region.

20. The method of claim 17, wherein the intermediate region extends in a direction away from the surface at least as far as the furthermost extremity of the first and second photodetection regions in the direction away from the surface.

21. The method of claim 17, wherein the intermediate region occupies substantially all space between the first and second photodetection regions.

22. The method of claim 17, wherein the intermediate region consists essentially of epitaxial silicon material present at the start of CMOS processing.
